(19) United States
(12) Patent Application Publication
(10) Pub. No.: US 2024/0404857 A1
(43) Pub. Date: Dec. 5, 2024

(54) SYSTEMS AND METHODS FOR MANAGING SEISMIC FORCES

(71) Applicant: Taiwan Semiconductor Manufacturing Co., Ltd., Hsinchu (TW)

(72) Inventors: Chen-Hao LIAO, Hsinchu (TW); Pei-Yu LEE, Hsinchu (TW); Chih-Tsung LEE, Hsinchu (TW); Cheng-Lung WU, Hsinchu (TW); Jiun-Rong PAI, Hsinchu (TW)

(21) Appl. No.: 18/412,310

(22) Filed: Jan. 12, 2024

Related U.S. Application Data
(60) Provisional application No. 63/505,382, filed on May 31, 2023.

(51) Int. Cl. H01L 21/677; H01L 21/324; H01L 21/673

(52) U.S. Cl. CPC H01L 21/67742; H01L 21/324; H01L 21/67303

(57) ABSTRACT

Base plates of a substrate retainer transportation mechanism are provided with damping members to assist elastic members in damping and limiting movement of the substrate retainer transportation mechanism when the substrate transportation mechanism is subjected to unwanted external forces, e.g., seismic forces. By damping and limiting movement of the substrate retainer transportation mechanism, undesirable damage to substrates contained in a substrate retainer being carried by the substrate retainer transport mechanism can be minimized.

### BACKGROUND

High temperature heat-treatment (annealing) of semiconductor wafers is commonly used to achieve certain desirable characteristics. For example, such a process may be used to create a defect free layer of silicon on the wafers or form a silicon nitride film. Such high temperature processes are typically carried out in a vertical furnace which subjects the wafers to elevated temperatures.

During such high temperature heat-treatment, the wafers should be adequately supported to avoid slip or deformation due to local gravitational and thermal stresses. In some processes, vertical wafer boats are used to adequately support semiconductor wafers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram schematically illustrating a perspective view of a substrate processing apparatus according to one or more embodiments described herein.

FIG. 2 is a diagram schematically illustrating a vertical cross-section of a process furnace of the substrate processing apparatus according to the embodiments described herein.

FIG. 3 is a diagram schematically illustrating an enlarged view of a main configuration of a substrate retainer and substrate retainer transport mechanism according to the embodiments described herein.

FIG. 4 is a top plan view of a portion of the substrate retainer transport mechanism in accordance with an embodiment of the present disclosure.

FIG. 5 is a top plan view of a portion of the substrate retainer transport mechanism in accordance with an embodiment of the present disclosure.

FIGS. 6A and 6B are a perspective views of a damping mechanism in accordance with an embodiment of the present disclosure.

FIG. 7 is a schematic side view of a portion of a substrate retainer transport mechanism in accordance with an embodiment of the present disclosure.

FIG. 8 is a flow diagram of a method in accordance with an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

One embodiment described herein is a method for processing a substrate in a substrate processing apparatus that includes a support for supporting a substrate having a front side and a backside, e.g., a substrate boat. The substrate boat includes a top plate, a bottom plate and a plurality of boat rods extending between the top plate in the bottom plate. Each of the plurality of boat rods includes a finger that includes a substrate contact surface for receiving and supporting a substrate. The substrate contact surface contacts an underside of a substrate supported by the substrate boat. The substrate support or substrate retainer is moved within the substrate processing apparatus by several different substrate support transport mechanisms. For example, one example of a substrate transport mechanism includes an elevator for moving the substrate support in a vertical direction. Another example of a substrate transport mechanism is a robot for moving the substrate support in a horizontal direction. In accordance with embodiments of the present disclosure, the substrate transport mechanism includes a combination of purposefully arranged elastic members and damping members which combine to absorb forces, e.g., unexpected seismic forces, acting upon the substrate support. In embodiments described herein, the substrate processing apparatus can be a furnace for heating/annealing the substrates. In some embodiments, processes for forming thin films on the substrate are carried out in the substrate processing apparatus. One example of a process for forming thin films is atomic layer deposition.

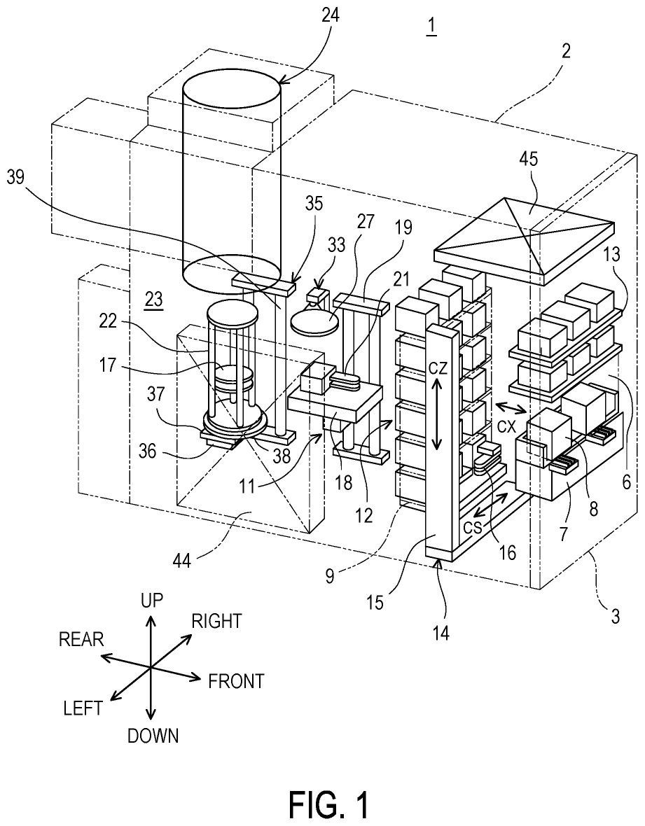

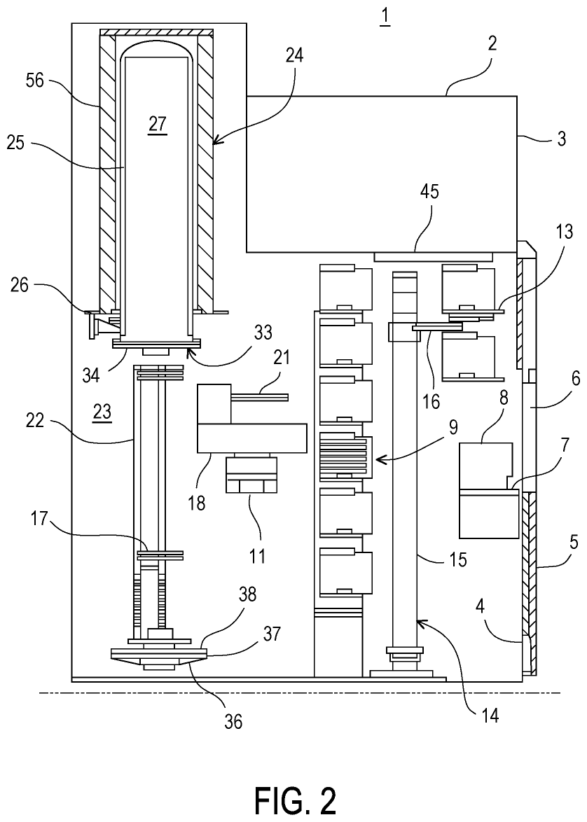

Referring to FIGS. 1 and 2, A substrate processing apparatus 1 includes a housing 2. A front maintenance port 4 serving as an opening provided for maintenance is provided at a lower portion of a front wall 3 of the housing 2. The front maintenance port 4 is opened and closed by a front maintenance door 5.

A pod loading/unloading port 6 is provided at the front wall 3 of the housing 2 so as to communicate with an inside and an outside of the housing 2. The pod loading/unloading port 6 may be opened or closed by a front shutter (not shown). A loading port (which is a loading port shelf) 7 is provided at the pod loading/unloading port 6. The loading port 7 is configured such that a pod 8 is aligned while placed on the loading port 7.

The pod 8 is a sealed type substrate container. The pod 8 may be transferred into and placed on the loading port 7 by an in-process transfer apparatus (not shown) and transferred from the loading port 7 by the in-process transfer apparatus.

A pod shelf 9 is provided at a substantially center portion in a front-rear direction in the housing 2. The pod shelf 9 is configured to store a plurality of pods including the pod 8 in a plurality of stages and a plurality of rows. A transfer shelf 12 configured to accommodate the pod 8 to be transferred by a wafer transfer structure (hereinafter, also referred to as a “transfer device”) 11 is provided at the pod shelf 9. A spare pod shelf 13 is provided above the loading port 7, and is configured to store the pod 8 in reserve.

A pod transfer device 14 is provided between the loading port 7 and the pod shelf 9. The pod transfer device 14 may be constituted by: a pod elevator 15 capable of elevating and lowering the pod 8 in a CZ axis direction shown in FIG. 1 while holding (or supporting) the pod 8; and a pod transfer structure 16 capable of making forward, backward and rotational movements of the pod 8 in a CX axis direction and a CS axis direction shown in FIG. 1. In cooperation with the pod elevator 15 and the pod transfer structure 16, the pod transfer device 14 is configured such that the pod 8 can be transferred among the loading port 7, the pod shelf 9 and the spare pod shelf 13.

The transfer device 11 is provided behind the pod shelf 9. For example, the transfer device 11 is constituted by: a wafer transfer device 18 capable of rotating or moving the wafer 17 horizontally; and a wafer transfer device elevator 19 capable of elevating and lowering the wafer transfer device 18.

The wafer transfer device 18 may include a predetermined number of wafer mounting plates (which are substrate supports) 21 on which a predetermined number of wafers including the wafer 17 are mounted. For example, as shown in FIG. 1, three wafers can be mounted on three wafer mounting plates 21. In cooperation with the wafer transfer device 18 and the wafer transfer device elevator 19, the transfer device 11 is configured to load the wafer 17 into a boat (which is a substrate retainer) 22 and to unload the wafer 17 out of the boat 22. Further, a notch alignment device (not shown) serving as a substrate alignment device configured to align a circumferential position of the wafer 17 may be provided in the vicinity of the transfer device 11.

In a rear region of the housing 2, a standby space 23 where the boat 22 is accommodated and in standby is provided, and a vertical type process furnace 24 is provided above the standby space 23. The process furnace 24 may be constituted by: a reaction tube 25 in which the wafer 17 is processed; and an inlet flange 26 provided at a lower end of the reaction tube 25. For example, the inlet flange 26 is made of stainless steel. A reaction chamber 27 is defined inside the process furnace 24. A heater 56 is provided around the reaction chamber 27. The inlet flange 26 is of a cylindrical shape. A supply port 28 through which various process gases are supplied into the reaction chamber 27 and an exhaust port 29 through which an inner atmosphere of the reaction chamber 27 is exhausted are provided on a peripheral surface of the inlet flange 26. Further, an upper flange 31 and a lower flange 32 are provided at an upper end and a lower end of the inlet flange 26, respectively, and an opening (also referred to as a “furnace opening”) is provided at a lower end portion of the lower flange 32.

The furnace opening is opened and closed by a furnace opening shutter (lid opening/closing structure) 33. The furnace opening shutter 33 includes a lid 34. The furnace opening shutter 33 is configured to open or close the furnace opening by moving the lid 34 between a standby position and a furnace opening position. In the standby position, the lid 34 is retracted to a position where the lid 34 does not come into contact with other components such as the boat 22, and in the furnace opening position, the lid 34 is configured to airtightly close the furnace opening.

A substrate retainer transfer mechanism 35 configured to elevate the substrate retainer 22, e.g., a substrate boat, into the reaction chamber 27 or lower the substrate retainer 22 from the reaction chamber 27 is provided in the standby space 23. A moving structure configured to insert the substrate retainer 22 into the reaction chamber 27 and to pull out the substrate retainer 22 from the reaction chamber 27 is constituted by the substrate transfer mechanism 35, the furnace side arm 36 and the base 37. A seal cap 38 serving as a lid is horizontally provided on the base 37. Lowering or raising of the furnace side arm 36, base 37 and seal cap 38 by the substrate retainer transfer mechanism 35 results in the substrate retainer 22 being introduced into or removed from the reaction chamber 27.

A clean air supply structure (which is a clean air supplier) 44 is arranged at a position facing the substrate support transfer mechanism 35. The clean air supply structure 44 is constituted by a supply fan and a dustproof filter so as to supply clean air such as an inert gas and a clean atmosphere.

The clean air ejected from the clean air supply structure 44 is circulated in components such as the transfer device 11 and the substrate retainer 22. Thereafter, the clean air is exhausted out of the housing 2 through a duct 45 provided above the pod shelf 9, or is ejected again into the housing 2 by the clean air supply structure 44.

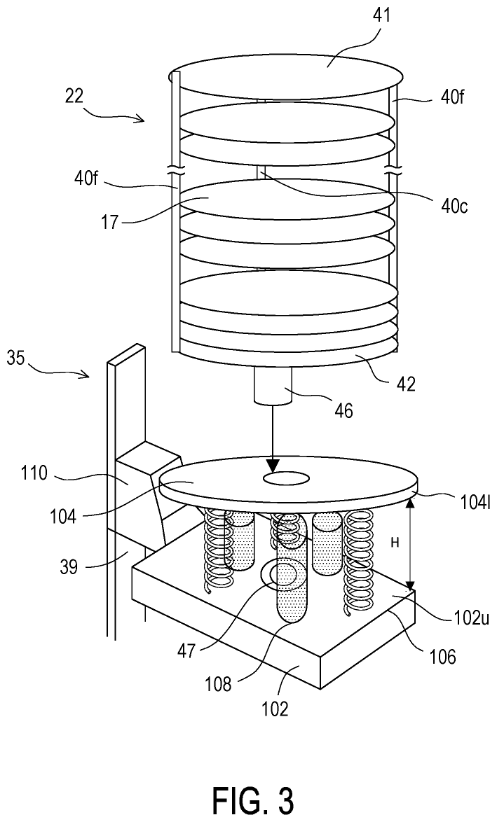

FIG. 3 illustrates a portion of an embodiment of a substrate retainer 22 of FIGS. 1 and 2, in accordance with the present disclosure. The substrate retainer 22 includes spaced-apart support rods 40c and 40f (e.g., boat rods) that are affixed at their top to a top plate 41 of the boat and at their base to a bottom plate 42 of the boat. Such fixation helps to retain the positions of the rods relative to each other. When the substrate retainer 22 is placed in a vertical process chamber, such as a furnace, the support rods 40c and 40f are generally vertical. In the illustrated embodiment, the substrate retainer 22 has a central rod 40c and two forward rods 40f. In the embodiment illustrated in FIG. 3, the underside of bottom plate 42 includes a coupling 46 that is centered on the bottom plate. The coupling can be connected to a drive mechanism, e.g., a substrate retainer rotator 47 described in more detail below.

The support rods 40c and 40f each support a plurality of laterally extending retainer fingers (not shown). The fingers may be integrally formed on the support rods. Alternatively, cuts or slots may be made in an elongate one-piece structure of the rods 40c and 40f, forming a slot for receiving the fingers and securing them to support rods 40c and 40f. Each finger includes a top side upon which an underside of the substrate 17 rests when placed within boat 22. The fingers of the substrate retainer 22 are arranged in groups lying in different common generally horizontal planes along the vertical length of the support rods 40c and 40f. The fingers that lie in a same generally horizontal plane engage and support a same substrate 17. The fingers that lie in a same generally horizontal plane contact a backside a common substrate 17. The entire substrate retainer 22 may be made of quartz, a silicon carbide material, or other suitable material that is mechanically stable and chemically inert with respect to the processing conditions to which it will be exposed, including high temperatures.

In use, the substrate retainer 22 is readied by placing substrates, e.g., wafers 17, into the substrate retainer 22 so that each wafer is placed on the top surface of three retainer fingers that lie in the same horizontal plane. The wafers can be loaded into the substrate retainer 22 boat via a robotic arm. Once the substrate retainer 22 is loaded with a predetermined number of wafers, the substrate retainer is received in the process chamber where a high-temperature heat treatment or other thermal treatment is performed. After heat treatment and other treatment, the wafers, the substrate retainer 22 is removed from the process chamber and the wafers are unloaded from the substrate retainer 22, e.g., using a robotic arm.

FIG. 3 illustrates a schematic view of a portion of the substrate processing apparatus illustrated in FIGS. 1 and 2. FIG. 3 illustrates an embodiment of a substrate processing apparatus that utilizes a substrate retainer 22 in the form of a substrate boat; however, embodiments of the present disclosure are not limited to substrate processing apparatuses that utilize a substrate boat. For example, the force absorbing systems described below in more detail can be implemented in a substrate processing apparatus that utilizes a substrate retainer 22 that is not a substrate boat. The portion of a substrate processing apparatus illustrated in FIG. 3 includes a substrate retainer transport mechanism 35, e.g., a substrate retainer elevator, that includes a substrate retainer transport mechanism track 39, a substrate retainer support which includes a substrate retainer support base 102, a substrate retainer support cap 104, a plurality of elastic members 106 and a plurality of damping members 108, wherein the plurality of elastic members 106 and the plurality of damping members 108 are between the substrate retainer support base 102 and the substrate retainer support cap 104.

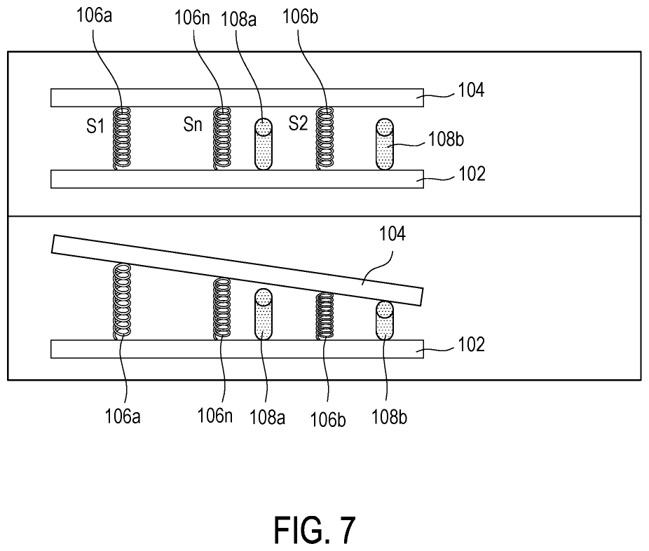

Referring to FIG. 7 in combination with FIG. 3, embodiments in accordance with the present disclosure are directed to substrate processing apparatuses and systems that include a force absorbing subsystem or damping system. Force absorbing subsystems or damping subsystems formed in accordance with the present disclosure absorb abnormal external forces exerted upon a substrate retainer being processed by the substrate processing apparatus or system. During normal operation, during which abnormal external forces are absent, substrate retainer 22 will experience normal forces caused by the normal operation of substrate retainer transport mechanism 35. Such normal forces include vibration or oscillations originating from things like the movement of substrate retainer elevator or a drive mechanism which rotates the substrate retainer. One example of abnormal external forces includes forces caused by an unexpected seismic event, e.g., an earthquake. The top image in FIG. 7 illustrates the status of the force absorbing subsystem during normal operation when no abnormal external undesirable forces are being exerted. In the top image in FIG. 7, elastic members 106a, 106b and 106n support substrate retainer support 104 cap above substrate retainer support base 102 in a generally horizontal position relative to a vertical gravity vector. When no abnormal undesirable external forces are being exerted on the substrate retainer, clastic members 106a, 106b and 106n provide effective stability to the substrate retainer support 104, helping to maintain substrate retainer support 104 in its desired position and minimizing movement of the substrate retainer that could cause substrates supported in the substrate retainer to move and be damaged. The bottom image in FIG. 7 illustrates an abnormal undesirable external force acting on the substrate retainer, such as a seismic event, and the effect such abnormal force can have the movement of substrate retainer support 104, especially movement of the substrate retainer support cap 104 relative to the substrate retainer support base 102. For example, during a seismic event, the substrate retainer support cap 104 may move out of a horizontal position to an undesirable angled position illustrated in the bottom image. Such movement may cause substrates within the substrate retainer to move and become damaged. In addition, such movement can have a frequency that results in substrates within the substrate retainer being jostled and moved in a way that can lead to damage of the substrates. In the bottom image in FIG. 7, at least elastic member 106b is able to compress and absorb some of the movement of the substrate retainer support out of the horizontal plane. In accordance with embodiments of the present disclosure, damping member 108b serves to dampen the movement of the substrate retainer support cap 104 by coming in contact with the underside of substrate retainer support cap 104 and absorbing, e.g., by being compressed, a portion of the force created by the abnormal movement of the substrate retainer support cap 104. Thus, in accordance with embodiments of the present disclosure, damping members 108a, 108b and 108n and elastic members 106a, 106b and 106n combine to restrict movement of the substrate retainer support cap 104 and dampen the frequency of the movement of the substrate retainer support cap 104 when the substrate retainer support is subjected to an abnormal undesirable external force.

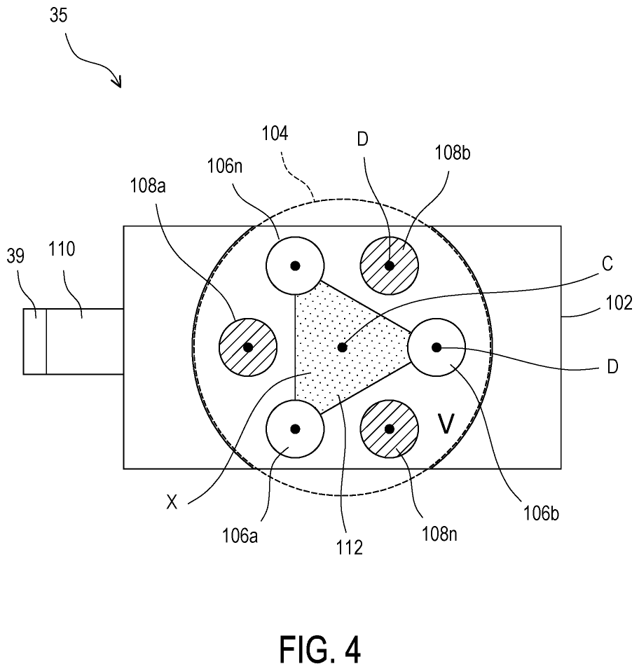

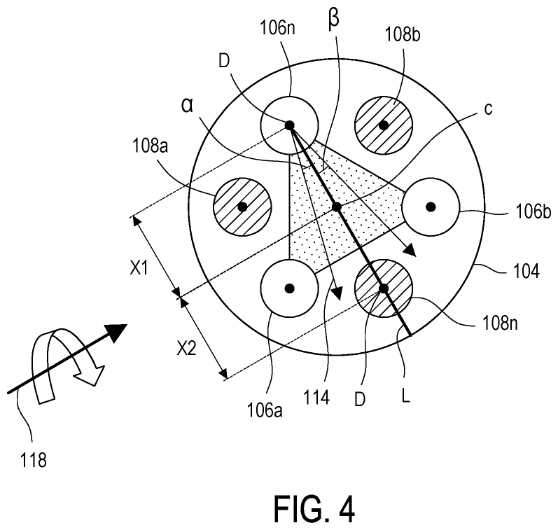

Referring to FIG. 3, the substrate retainer transport mechanism 35 includes a substrate retainer transport mechanism track 39 which in the embodiment of FIG. 3 is oriented in a vertical direction. Substrate retainer transport mechanism track 39 includes a drive mechanism (not shown) designed to cooperate with a substrate retainer arm 110 to move substrate retainer arm 110 up and down along substrate retainer transport mechanism track 39. Substrate retainer arm 110 includes one side attached to substrate retainer transport mechanism track 39 and another side opposite from the side attached to substrate retainer transport mechanism track 39 connected to a substrate retainer support base 102. In the illustrated embodiment, substrate retainer support base 102 is a rectangular plate extending in a horizontal plane. Substrate retainer support base 102 includes a transport retainer rotation mechanism 47 for coupling to rotation coupling 46 of substrate retainer 22. Transport retainer rotation mechanism 47 includes a drive mechanism, which when activated, causes the substrate retainer to rotate. Substrate retainer support base 102 includes an upper surface 102u. Upper surface 102u supports the lower ends of three damping members 108 and the lower ends of three elastic members 106. Details of the structure and position of the three damping members 108 and three elastic members 106 are provided below with reference to FIGS. 4, 5, 6A and 6B. The upper ends of each of the three elastic members 106 contact a lower surface 1041 of the substrate retainer support cap 104. In some embodiments, the upper ends of each of the three elastic members 106 are connected to a lower surface 1041 of substrate retainer support cap 104. In some embodiments, the three damping members 108 rest on substrate retainer support base 102 but are not attached to substrate retainer support base 102. In other embodiments, one or more of the three damping members 108 can be attached to substrate retainer support base 102. The upper ends of each of the three damping members 108 are in close proximity to, but do not contact the lower surface 1041 of the substrate retainer support 104 when the substrate retainer transport mechanism 35 is operating under normal conditions, free of any abnormal unexpected external forces. During normal operation, the distance between the upper surfaces of the damping members 108 and the lower surface 1041 of the substrate retainer support cap 104 can vary, depending upon the amount of movement of the substrate retainer support 104 that can be tolerated during exposure of the substrate retainer support cap 104 to abnormal unwanted external forces. When abnormal unwanted external forces act upon support cap 104, as described above, lower surface 1041 of substrate retainer support cap 104 can come into contact with an upper surface of one or more damping members 108. In this manner, the degree of movement and the intensity of the oscillation of substrate retainer support cap 104 relative to substrate retainer support base 102 is dampened and minimized. In FIG. 3, the upper surface 102u of substrate retainer support base 102 and the lower surface 1041 of substrate retainer support cap 104 are spaced apart by a distance identified by dimension H.

FIG. 4 is a top plan view of the substrate retainer transport mechanism 35 described above with reference to FIGS. 3 and 7. In FIG. 4, the position of the substrate retainer support cap 104 is represented by a broken line so that the locations of the underlying elastic members 106 and damping members 108 can be readily observed. The embodiment of FIGS. 3 and 4 illustrate a substrate retainer transport mechanism 35 that includes three elastic members, 106a, 106b and 106n and three damping members 108a, 108b and 108n. In accordance with other embodiments, a substrate retainer transport mechanism may include more than three clastic members and more than three damping members. In the embodiment of FIG. 4, the three elastic members 106a, 106b and 106n are round springs. Each of the round springs includes a central axis E which is positioned at a respective one of the three vertices of an equilateral triangle X. Equilateral triangle X has its centroid C positioned on the center of substrate retainer support cap 104. Examples of suitable round springs include round springs used to support a substrate retainer support cap 104 of a furnace used to process semiconductor substrates, such as semiconductor wafers.

In FIG. 4, the portion of the substrate retainer support cap 104 that overlaps the substrate retainer support base 102 and does not overlap with the equilateral triangle X, is shaded and corresponds to a damping region V where one or more damping members 108 are positioned in accordance with embodiments of the present disclosure. In the embodiment of FIG. 4, three damping members 108a, 108b and 108n are located in damping region V. When damping members 108a, 108b and 108n are located in damping region V, they are able to come in contact with substrate retainer support cap 104 at locations where elastic members 106a, 106b and 106n are not in contact with substrate retainer support cap 104.

In FIG. 5, further details of the locations of elastic members 106 and damping members 108 are illustrated. In FIG. 5, clastic members 106 and damping members 108 are illustrated in locations similar to the locations described above with reference to FIG. 4. Generally, a damping member is positioned so it mirrors the position of the elastic member positioned on the opposite side of centroid C. When arranged in these positions, the likelihood of the substrate retainer support cap 104 rotating around a rotation axis, such as the rotation axis 118 in FIG. 5 is reduced. In FIG. 5, a first angle α exists between ray 114 and the line L that extends through the central axis D of elastic members 106n, the location of centroid C and the central axis D of damping member 108n. A second angle β exists between ray 116 and line L. In some embodiments, angle α and angle β less than 30°. In some embodiments, angle α and angle β are equal. In other embodiments, angle α and angle β are not less than 30°. When angle α and angle β are not less than 30°, the likelihood of rotation about a rotation axis similar to rotation axis 118 increases compared to when angle α and angle β are greater than 30°. In some embodiments, angle α and angle β are not equal. In the embodiment of FIG. 5, damping member 108n is located between rays 114 and 116.

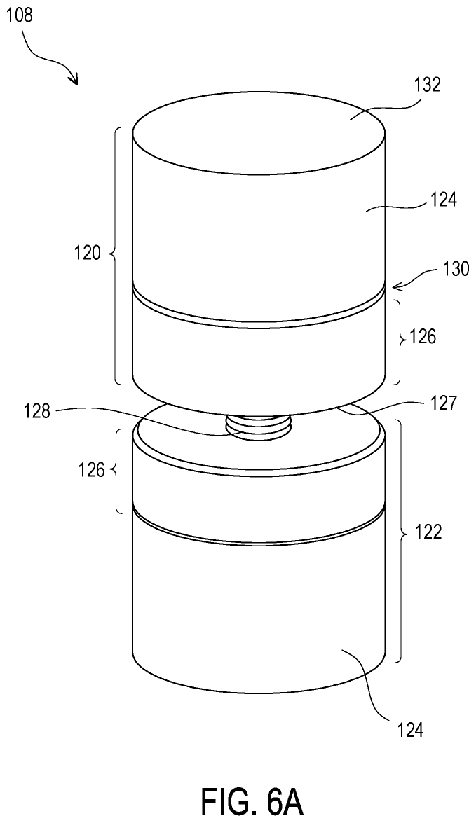

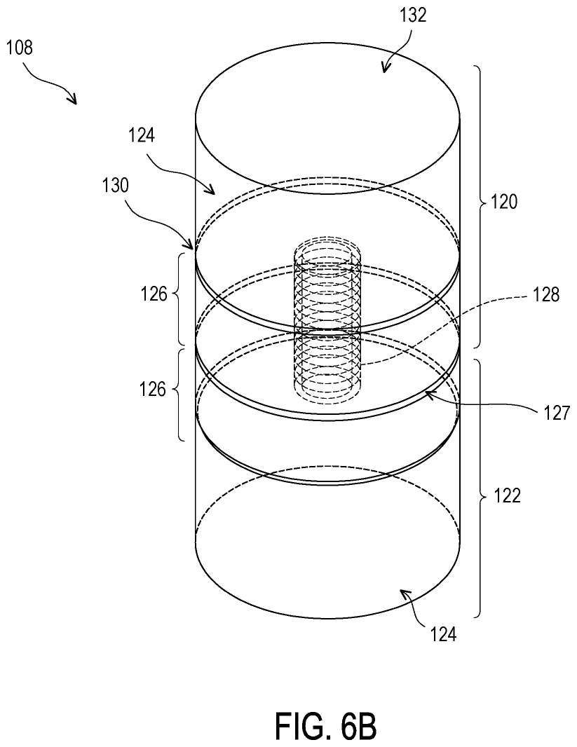

FIGS. 6A and 6B illustrate an example of an adjustable damping member 108 formed in accordance with embodiments of the present disclosure. Damping member 108 in FIGS. 6A and 6B includes an upper portion 120 and a lower portion 122. As upper portion 120 and lower portion 122 are mirror images of each other, the description below regarding upper portion 120 applies equally to lower portion 122. Upper portion 120 includes a damping material segment 124 and a connector segment 126. In the embodiment of FIGS. 6A and 6B, both damping material segment 124 and connector segment 126 are cylindrical in shape having a round cross-section. In other embodiments, damping material segment 124 and connector segment 126 are cylindrical in shape but do not have a round cross-section. For example, damping material segment 124 and connector segment 126 have cross-sections that are oval, elliptical or polygonal. In some embodiments, damping material segment 124 has a cross-section that is different in shape than the cross-section of the connector segment 126.

In one embodiment, connector segment 126 is formed of a heat and corrosive resistant material, such as stainless steel, or some other metal or composite material. Connector segment 126 of upper portion 120 of damping member 108 includes lower surface 127 that includes a central bore which is threaded to receive one end of threaded member 128, such as a threaded rod. In some embodiments, the central bore extends entirely through connector segment 126 and in other embodiments, the central bore does not extend entirely through connector segment 126. The other end of threaded member 128 is received into the threaded bore of connector segment 126 of lower portion 122 of damping member 108. The length of damping member 108 can be adjusted by adjusting the position of the upper portion 120 relative to the lower portion 122 by screwing the upper portion 120 and/or lower portion 122 along the length of threaded member 128. Embodiments in accordance with the present disclosure are not limited to utilization of a threaded bore and a threaded member to adjust the length of damping member 108. For example, in other embodiments, other arrangements for making the length of damping member 108 adjustable can be utilized.

Connector segment 126 includes an upper surface 130 at an end of the connector segment 126 that is opposite to the end of connector segment 126 that includes lower surface 127. Upper surface 130 of connector segment 126 is joined to damping material segment 124. Upper surface 130 of connector segment 126 can be joined to damping material segment 124 several different ways, for example, by an adhesive, by mechanical fasteners, or other means. As noted above, lower portion 122 is a mirror image of upper proportion 120. Damping material segment 124 of upper portion 124 includes an upper surface 132 opposite to the surface of damping material segment 124 that is adjacent to upper surface 130 of connector segment 126. As noted above, the description above regarding upper portion 120 is equally applicable to lower portion 122. Damping material segment 124 is formed of a material having spring constant that is less that the spring constant of the elastic members 106. Examples of materials from which damping material segment 124 is formed include nitrile butadiene rubber (NBR) or Viton™ brand high performance fluoroelastomers. The material of the damping material segment 124 exhibits a damping ratio of greater than 0.1 or greater than 0.5. Damping ratio (ζ) is a dimensionless measure describing how oscillations in a system decay after a disturbance. Many systems exhibit oscillatory behavior when they are disturbed from their position of static equilibrium. A mass suspended from a spring, for example, might, if pulled and released, bounce up and down. On each bounce, the system tends to return to its equilibrium position, but overshoots it. Sometimes losses (e.g. frictional) damp the system and can cause the oscillations to gradually decay in amplitude towards zero or attenuate. The damping ratio is a measure describing how rapidly the oscillations decay from one bounce to the next. The material of the damping material segment 124 also should be resistant to damage or degradation when exposed to temperatures above 30° C. and in other embodiments, above 100° C.

In some embodiments, the height of a damping member 108 is greater than 1 cm and less than the height H. In some embodiments, height H can be 20 cm or less. In other embodiments, height H can be greater than 20 cm.

In accordance with some embodiments, upper surface 132 of damping material segment 124, that may come in contact with lower surface 1041 of substrate retainer support cap 104 during an abnormal undesirable seismic event, has a surface area that is greater than the area of contact between lower surface 1041 and an elastic member 106. In the embodiment of FIGS. 3, 4 and 5, the combined surface area of upper surface 132 of damping material segment 124 of damping members 108a, 108b and 108n is greater than the combined surface area of contact between lower surface 1041 and elastic members 106a, 106b and 106n. When the combined surface area of upper surface 132 of damping material segment 124 of damping members 108a, 108b and 108n is greater than the combined area of contact between lower surface 1041 and elastic members 106a, 106b and 106n favorable damping of movement of the substrate retainer support cap 104 caused abnormal external forces can be achieved.

In accordance with some embodiments of the present disclosure, the coefficient of static friction u between the material of the damping material segment 124 and the material of the substrate retainer support base 102 is chosen so that the risk a damping member 108 will slide on the substrate retainer support base 102 to a position where its ability to dampen movement of the substrate retainer support cap 104 will be compromised is minimized. In some embodiments, the coefficient of static friction u between the material of the damping material segment 124 and the material of the substrate retainer support base 102 is greater than about 0.14. For embodiments where the damping member 108 rests on substrate retainer support base 102 but is not secured to substrate retainer support base 102, this level of static friction reduces the risk that the damping member 108 will slide on the substrate retainer support base 102 to a position where its ability to dampen movement of the substrate retainer support cap 104 will be compromised.

In accordance with embodiments of the present disclosure, damping members 108 and elastic members 106 can be positioned at different locations on the surface of substrate retainer support base 102. In the embodiment illustrated in FIGS. 4 and 5, damping member 108n is located a distance from clastic member 106n that is greater than X1+X2, where X1=distance between the central axis D of clastic member 106n and the centroid C of equilateral triangle X which coincides with the central axis of substrate retainer support cap 104 and

$$X 2 = \frac{1}{2} * X 1 + \frac{1}{H} * X 1$$

where H is the distance between lower surface 1041 of substrate retainer support cap 104 and the upper surface 102u of substrate retainer support base 102.

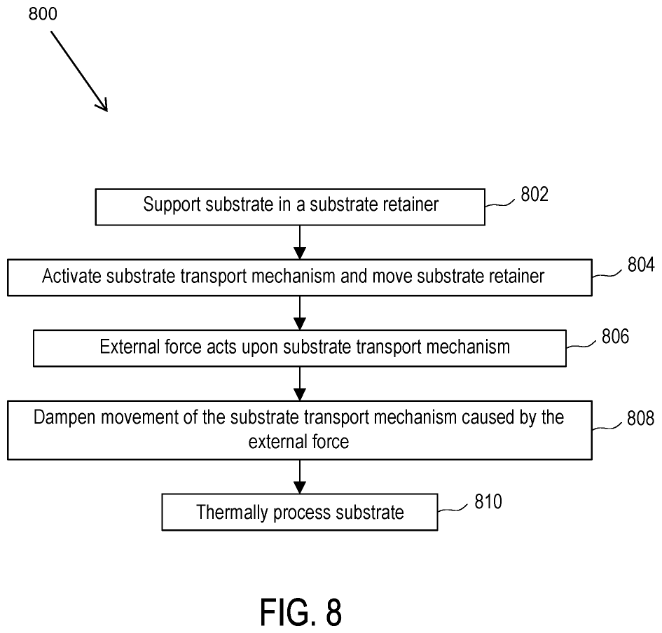

FIG. 8 is a flow diagram of a method 800 for processing a substrate in accordance with embodiments of the present disclosure. The various steps of method 800 can be carried out utilizing the substrate processing apparatus/system described above. Method 800 begins at operation 802 by supporting a substrate in a substrate retainer, such as the substrate retainer 22 described above with reference to FIG. 3. Method 800 proceeds to operation 804. Operation 804 includes activating a substrate transport mechanism and moving the substrate retainer 22 from one position to a different position within a substrate processing system. Operation 804 can be carried out by activating a substrate transport mechanism 35 described above with reference to FIG. 3. In accordance with embodiments of FIG. 8, the substrate transport mechanism is acted upon by an abnormal external force, e.g., a seismic forces. When the abnormal seismic forces are large enough or of a sufficient frequency, to cause portions of the substrate transport mechanism, e.g., the substrate retainer support base 102, to vibrate, oscillate or move in some other unwanted manner outside of normal process tolerances, method 800 proceeds to operation 808. At operation 808, the abnormal unwanted movement of the substrate transport mechanism is dampened by the action of elastic members 106 and damping members 108 as described above with reference to FIGS. 2, 4 and 7. Thereafter, method 808 proceeds to thermally process substrates in the substrate retainer at operation 810.

The thermal processing methods and systems have utility in an atomic layer deposition process. In an atomic layer deposition process, excited species of processing gases may be generated to assist in the atomic layer deposition. These species may be excited by plasma assistance, UV assistance (photo assistance), ion assistance (e.g., ions generated by an ion source), or combinations thereof. The species are excited in or in the vicinity of the process region within the chamber housing to avoid relaxation of the excited states before the ions reach the process region of the batch processing chamber. ALD processes can be carried out in a chamber also capable of thermally processing a substrate, such as a substrate processing apparatus or system described above. Embodiments of the present disclosure include other material deposition processes that can be carried out in a chamber capable of thermally treating substrates.

In one embodiment of the present disclosure, a method for processing a substrate that includes a step of supporting a substrate in a substrate retainer. In accordance with such method, a substrate retainer transport mechanism is activated causing the substrate retainer to move. The substrate retainer transport mechanism includes a transport mechanism track, a substrate retainer support base, a substrate retainer support cap, a plurality of elastic members between the substrate retainer support base and the substrate retainer support cap and a plurality of damping members between the substrate retainer support base and the substrate retainer support cap. The method further includes thermally processing the substrate in the substrate retainer.

In another embodiment of the present disclosure, a substrate processing apparatus that includes a substrate retainer and a substrate retainer transport mechanism. The substrate retainer transport mechanism includes a transport mechanism track, a substrate retainer support base, a substrate retainer support cap, a plurality of elastic members between the substrate retainer support base and the substrate retainer support cap and a plurality of damping members between the substrate retainer support base and the substrate retainer support cap.

In another embodiment of the present disclosure, a thermal processing system is provided that includes a substrate boat as described above. The system further includes a substrate boat elevator that includes a boat elevator track, a boat elevator arm base connected to the boat elevator track, a boat elevator arm cap, three springs between an upper surface of the boat elevator arm base and a lower surface of the boat elevator arm cap and a plurality of adjustable damping members between the upper surface of the boat elevator arm base and the lower surface of the boat elevator arm cap. In some embodiments each of the adjustable damping members includes an upper portion and a lower portion connected by a threaded member, each of the upper portion and a lower portion including a damping material segment attached to a connector segment. The system further includes a thermal processing chamber.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of processing a substrate, comprising:
supporting a substrate in a substrate retainer;
activating a substrate retainer transport mechanism and moving the substrate retainer, the substrate retainer transport mechanism including:
a transport mechanism track;
a substrate retainer support base;
a substrate retainer support cap;
a plurality of elastic members between the substrate retainer support base and the substrate retainer support cap; and
a plurality of damping members between the substrate retainer support base and the substrate retainer support cap; and
thermally processing the substrate in the substrate retainer.

2. The method of claim 1, wherein the supporting a substrate in a substrate retainer includes supporting a substrate in a substrate boat.

3. The method of claim 1, wherein the thermally processing the substrate in the substrate retainer includes forming a film on the substrate.

4. The method of claim 1, further comprising absorbing, by the plurality of elastic members and plurality of damping members, abnormal movement of the transport mechanism cap relative to the transport mechanism base.

5. The method of claim 4, wherein absorbing the abnormal movement of the transport mechanism cap relative to the transport mechanism base further includes damping the abnormal movement of the transport mechanism cap relative to the transport mechanism base.

6. The method of claim 5, wherein the damping the abnormal movement of the transport mechanism cap relative to the transport mechanism base includes maintaining the position of the damping members relative to the transport mechanism base.

7. The method of claim 4, wherein the absorbing the abnormal movement of the transport mechanism cap relative to the transport mechanism base further includes compressing one or more of the plurality of elastic members and contacting one or more of the plurality of damping members with the transport mechanism cap.

8. The method of claim 4, wherein the compressing one or more of the plurality of elastic members includes compressing one or more of a plurality of springs between the transport mechanism base and the transport mechanism cap.

9. A substrate processing apparatus, comprising:
a substrate retainer; and
a substrate retainer transport mechanism, the substrate retainer transport mechanism including:
a transport mechanism track;
a substrate retainer support base;
a substrate retainer support cap;
a plurality of elastic members between the substrate retainer support base and the substrate retainer support cap; and
a plurality of damping members between the substrate retainer support base and the substrate retainer support cap.

10. The substrate processing apparatus of claim 9, wherein each of the plurality of elastic members has a spring constant that is greater than a spring constant of each of the damping members.

11. The substrate processing apparatus of claim 9, wherein the plurality of elastic members is a plurality of springs.

12. The substrate processing apparatus of claim 9, wherein the substrate retainer is a substrate boat.

13. The substrate processing apparatus of claim 12, wherein the substrate retainer transport mechanism is a boat elevator.

14. The substrate processing apparatus of claim 9, wherein the substrate is a semiconductor wafer.

15. The substrate processing apparatus of claim 9, wherein the plurality of damping members includes at least one damping member including an upper member spaced apart from a lower member by a distance, the distance being adjustable.

16. The substrate processing apparatus of claim 15, wherein a threaded member extends between the upper member and the lower member.

17. A thermal processing system, comprising:
a substrate boat;
a substrate boat elevator, the substrate boat elevator including:
a boat elevator track;
a boat elevator arm base connected to the boat elevator track;
a boat elevator arm cap;
a three springs between an upper surface of the boat elevator arm base and a lower surface of the boat elevator arm cap; and
a plurality of adjustable damping members between the upper surface of the boat elevator arm base and the lower surface of the boat elevator arm cap, each of the adjustable damping members including an upper portion and a lower portion connected by a threaded member, each of the upper portion and the lower portion including a damping material segment attached to a connector segment; and
a thermal processing chamber.

18. The thermal processing system of claim. 17, wherein the connector segment includes a threaded bore.

19. The thermal processing system of claim. 17, wherein the threaded member is a threaded rod.

20. The thermal processing system of claim 17, wherein a coefficient of static friction greater than 0.14 exists between the damping material segment and the upper surface of the boat elevator arm base.
